(19) United States
(12) Patent Application Publication
(10) Pub. No.: US 2003/0231480 A1
(43) Pub. Date: Dec. 18, 2003

(54) Shielding apparatus for electrical modules

(76) Inventors: Eduard Mair, Munchen (DE); Sonja Morales Robles, Munchen (DE)

Correspondence Address: Kevin R. Spivak, Morrison & Foerster LLP, Suite 300, 1650 Tysons Boulevard, McLean, VA, 22102, US

(21) Appl. No.: 10/392,311

(22) Filed: Mar. 20, 2003

(30) Foreign Application Priority Data
Mar. 21, 2002 (DE) 102 12 615.1

(51) Int. Cl. H05K 9/00

(52) U.S. Cl. 361/816

(57) ABSTRACT

The limit values for the field strengths of emitted electromagnetic interference fields from electronic appliances and modules (BG1, BG2) are defined in guidelines, for example for communications devices in the regulation NEBS Level 3. Together with the limit values, the operating conditions are also always defined, in which the limit values must not be exceeded. For example, there is a requirement for the limit values to be complied with even during servicing, in which both the rack door and the door of the module shelf or module frame (T) are open. The appropriate limit values are regularly not complied with by existing systems when the door of the module shelf or module frame (T) is open, if, for example, the modules (BG1, BG2) of the existing systems are equipped with plastic shutters (2). The invention provides a shielding apparatus for electrical modules (BG1, BG2), with the shielding apparatus having an approximately rectangular metallic front panel (5) which is arranged on the module (BG1, BG2) such that it can be pivoted by means of a pivoting device (6), and the shielding effect is achieved in the pivoted-in state. The shielding apparatus according to the invention can be retrofitted to modules (BG1, BG2) of existing systems.

### CLAIM FOR PRIORITY

This application claims the benefit of priority from German Application No. 10212615.1 filed Mar. 21, 2002.

### FIELD OF INVENTION

This invention relates to a shielding apparatus, and more particularly to a shielding apparatus for electrical modules to reduce the interference emission thereof.

### BACKGROUND OF THE INVENTION

The limit values for the field strengths of interference emission, i.e., emitted electromagnetic interference fields, of electronic appliances and modules are defined in legal regulations and guidelines, for example, for communications devices in the regulation NEBS (Network Equipment Building Specification) Level 3, issued by Telcordia Technologies Inc., previously Bellcore. Together with the limit values, the operating conditions are also defined, under which the limit values must not be exceeded.

These regulations and guidelines are being repeatedly updated on the basis of new technical knowledge and updated requirements, for example, by new operating conditions being defined under which the limit values must be complied with. For example, there is a requirement for the limit values to be complied with even during servicing when both the rack door and the door of the module shelf or frame are open. These two doors in existing systems are, in most cases, intended to provide shielding against interference emissions.

In the past, there was no need to consider the interference emissions during servicing. Therefore, existing systems regularly do not comply with the corresponding limit values when the door of the module shelf is open. That is the case if, for example, the modules in the existing systems are equipped with plastic shutters or screens.

These limit values during servicing may, for example, be complied with by the modules being equipped with metallic shutters instead of with plastic shutters during the production process itself. However, in many cases, it is impossible to replace the plastic shutters of modules in existing systems by such metallic shutters. Therefore, it is necessary to find a solution which allows more effective shielding while retaining the plastic shutters of existing systems.

Known solutions envisage a modified module shelf or module frame which, in comparison to conventional module shelves or frames, additionally has individual front shutters for separate shielding of the modules. This has the disadvantage that conventional shelves, or frames, and racks are not suitable for this purpose, and special shelves, or frames, and rack designs are required for use with the individual front shutters.

It is, therefore, an object of the present invention to specify a shielding apparatus which reduces the interference emissions from electronic modules which are arranged in a module shelf or module frame, while taking into account existing front shutters.

### SUMMARY OF THE INVENTION

According to the invention, there is provided a shielding apparatus that advantageously comprises an approximately rectangular metallic front panel which is arranged on the module(s) such that it can be pivoted by means of a pivoting device and which achieves the shielding effect in the pivot-in state. This arrangement, which can pivot, allows the interference emissions from the modules which are arranged in a module shelf or module frame to be reduced considerably even when a door of the shelf or frame, which is normally closed during operation, is open. In particular, the interference emissions from all the other modules are effectively limited during servicing when, for example, it is necessary to replace one of the modules in the shelf or frame. Consequently, servicing personnel are better protected against the influences of electromagnetic fields, and the interference emissions are only insignificantly above the level which occurs during normal operation.

In accordance with one aspect of the present invention, existing systems which contain electrical modules can be retrofitted. The approximately rectangular metallic front panel is arranged on a board of the module, such that it can be pivoted, by means of a mounting panel on which the pivoting device is formed. The shielding apparatus is designed such that it can be retrofitted, in that attachment means for attachment of the mounting panel are arranged and formed on the board of the module such that existing attachment means of the board of the module are used. When it is in the pivoted-in state, the approximately rectangular metallic front panel runs approximately parallel to a plastic shutter on the module, if such a plastic shutter is provided.

One of the major advantages of the shielding apparatus according to the invention lies in its capability for retrofitting. New requirements, for example, those imposed by NEBS Level 3 for the interference emissions when doors are open, can be implemented with the aid of low-cost retrofit shielding apparatuses which are easy to install. The need to replace expensive modules of existing systems by redesigned modules is, thereby, eliminated. A further advantage is that the expensive redesign of modules, which would be carried out only in order to equip the modules with new shutters, is unnecessary, since the shielding apparatuses according to the invention can be retrofitted at low cost.

In order to achieve as best a shielding effect as possible, the metallic front panels of the shielding apparatus are equipped with contact springs, by means of which an electrical connection can be produced for the shielding apparatus of adjacent modules and for the shelf or frame.

### BRIEF DESCRIPTION OF THE DRAWINGS

The shielding apparatus according to the invention will be explained in more detail in the following text with reference to an exemplary embodiment and in conjunction with the figures, in which:

FIG. 1a shows a schematic illustration of the shielding apparatus according to the invention, with the front panel pivoted in;

FIG. 1b shows a schematic illustration of the shielding apparatus according to the invention, with the front panel pivoted out;

FIG. 2 shows a detailed schematic illustration of the area annotated D in FIG. 1a;

FIG. 3 shows a detailed schematic illustration of the area annotated E in FIG. 1b; and

FIG. 4 shows a schematic illustration of a module shelf or module frame, fitted with modules which are equipped with the shielding apparatuses according to the invention.

### DETAILED DESCRIPTION OF THE PREFERRED EMBODIMENTS

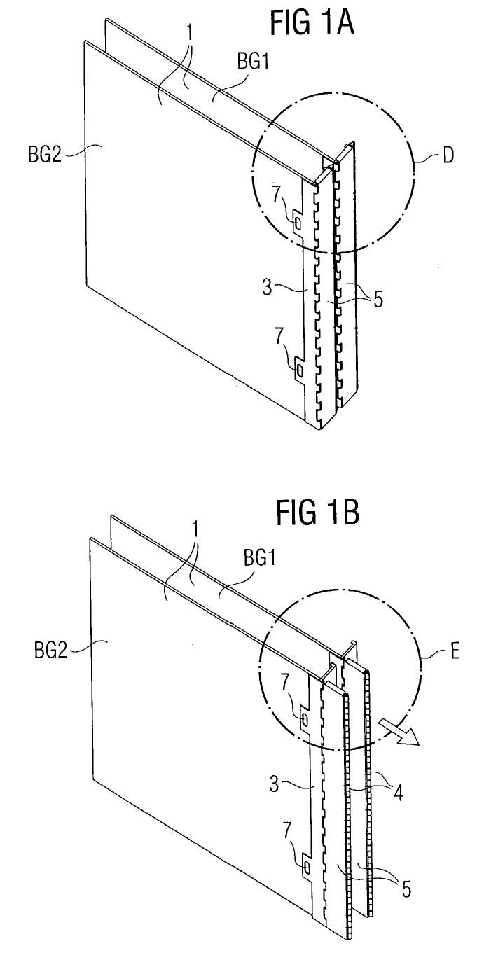

FIG. 1a shows two modules BG1, BG2, which each have a board 1 on which, in each case, one metallic mounting panel 3 is arranged using attachment means 7. To each of the mounting panels 3, a metallic front panel 5 is connected such that it can pivot. The front panels 5 are shown in the pivoted-in or closed state.

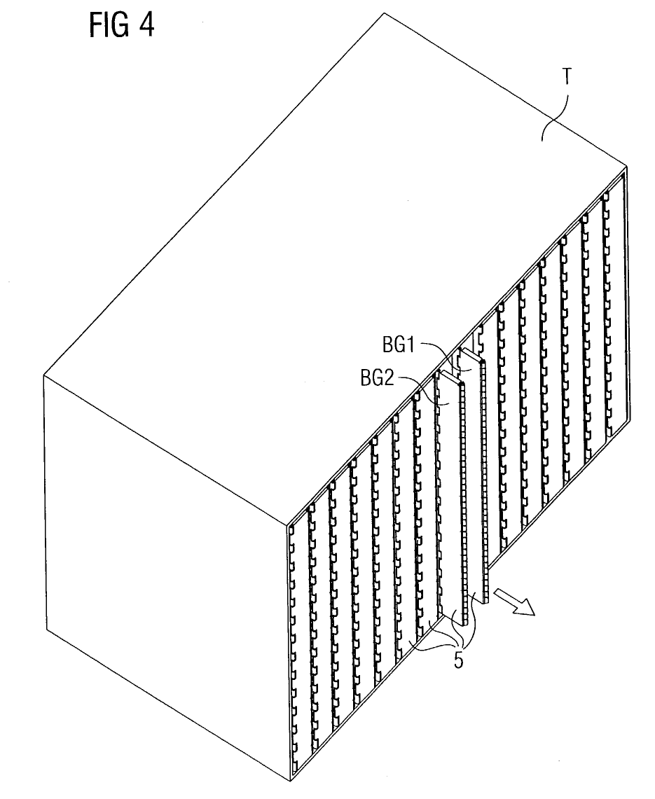

The front panels 5 have an approximately rectangular shape, with the dimensions of the front panels being chosen such that a chute (or slot), which is provided in a shelf or frame T for the modules BG1, BG2, is covered by the metallic front panels—see FIG. 4. FIG. 4 shows a shelf or frame which is fitted with modules that are equipped with the shielding apparatus according to the invention. Apart from the modules BG1, BG2, all front panels 5 are shown in the pivoted-in state. In the pivoted-in state, the front panels 5 form a closed shielding surface. It shall be understood, of course, that a small gap could be normally provided between the front panels of adjacent modules in order to compensate for manufacturing tolerances and to allow individual modules to be inserted and removed.

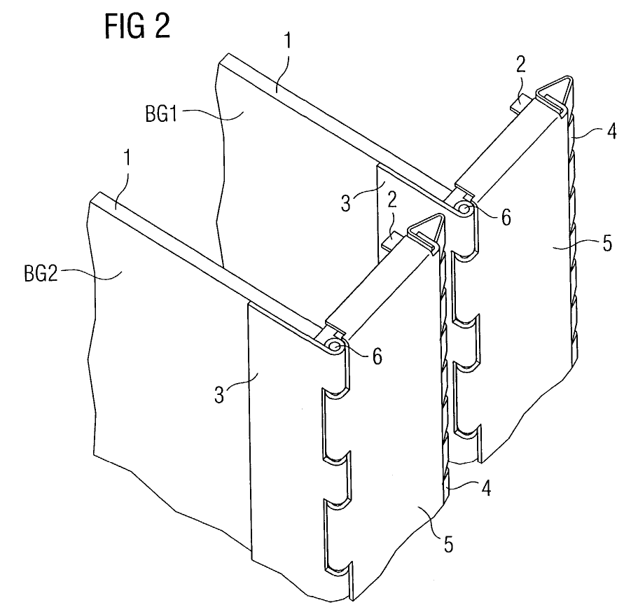

Contact springs 4 (FIG. 2) are provided in order to produce an electrical conductive connection between the shielding apparatuses of adjacent modules BG1, BG2 despite the gaps between the front panels 5 in the pivoted-in state. These contact springs 4 are fitted to that side of the front panel 5 which is opposite the mounting panel 3 and touch a contact surface of the mounting panel 3 of the shielding apparatus of the adjacent module BG1, BG2 when the front panel 5 of the first module BG1 is closed—see FIG. 2. A contact can likewise be made via the contact springs 4 with the shelf, or frame, T or with a metallic blank panel that is used instead of a module BG1, BG2—not shown.

FIG. 1b hows the modules BG1, BG2 from FIG. 1a, with the front panels 5 being shown in the pivoted-out or open state in FIG. 1b. FIG. 1b shows the contact springs 4 of the front panels 5. Further, contact springs can be fitted to the remaining two sides of the front panel 5, and thus produce an electrically conductive connection to the shelf or frame not shown.

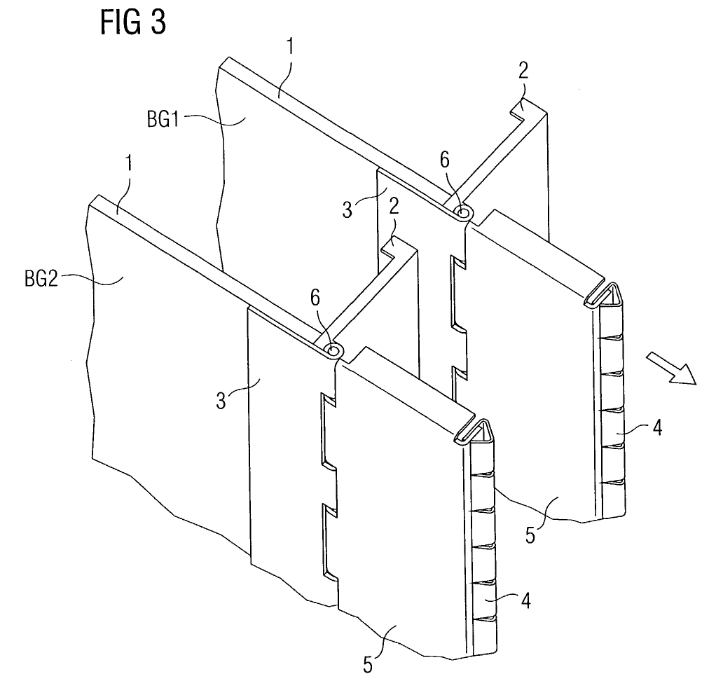

In order to allow the contact springs 4 and the further contact springs to be fitted, and in order to avoid sharp edges on the approximately rectangular front panel 5, the edges are preferably formed by approximately rectangular side limbs, which originally project beyond the desired size of the front panel 5 and are then bent approximately at right angles during the production process—see FIGS. 2 and 3. In the process, the side limbs are bent such that the side limbs point into the interior of the module shelf or module frame T when the front panels 5 are in the pivoted-in state.

The side limbs which are provided on the front panels 5 result in further advantages for the shielding apparatus. For example, the surfaces which are formed by the side limbs can be used as contact surfaces for contact springs, if these contact springs are not mounted on the side limbs of the front panel but on an appropriate opposite element. For example, these may be mounted on the shelf, or frame, T—not shown. In one advantageous embodiment, that side limb of the front panel 5, which is opposite the pivoting device, is used to hold the contact spring element 4, with the contact spring element 4 being attached onto the side limb and being secured with a force-fit by the influence of the contact springs 4.

In one preferred embodiment, the mounting panel 3 has two lugs for holding the attachment means 7 in order to mount the shielding apparatus on the board 1 of the module BG1, BG2. These attachment means 7 may be suitable holes (which may already be present for some other purpose) with screwed or riveted joints. Clamping or adhesively bonded attachments, possibly using a separately adapted mounting panel 3, may also be used. Other arrangements will be readily apparent to those skilled in the art.

FIG. 2 shows the detail D from the illustration in FIG. 1a. FIG. 2 shows a pivoting device 6, which connects the front panel 5 and the mounting panel 3 of the shielding apparatus. The pivoting device 6 is, in this case, in the form of a hinge strip, but may also be designed using individual hinges or using elastic bands. FIG. 2 also shows, in each case, one plastic shutter 2—partially concealed—of the modules BG1, BG2, which are normally arranged approximately at right angles to the board 1 on modules BG1, BG2 in existing systems. The modules BG1, BG2 have shielding against electromagnetic interference emissions added to them by means of the shielding apparatus according to the invention.

FIG. 3 shows the detail E from the illustration in FIG. 1b. The arrow indicates that modules BG1, BG2 can be removed. The front panel 5 of the shielding apparatus of the module BG2 adjacent to the module BG1 must, for example, be open in order to remove the module BG1, to prevent elements of the board 1 of the module BG1 to become trapped in the spring tongues of the contact springs 4 of the module BG2.

One important advantage of front panels 5 which are arranged such that they can pivot is that, in comparison to front panels which cannot move or are rigid, the component heights of the components which are arranged on the board BG1 are not restricted. A large number of existing modules make full use of the maximum physical heights, which are defined elsewhere, for insulated and uninsulated components. The restrictions involved with rigidly mounted front panels with contact springs are caused by the fact that the contact springs on the front panel of the adjacent module spring out during removal of a module and project beyond the module pitch or the intended chute, and restrict the component height. These problems are avoided by the shielding apparatus which can pivot according to the invention.

Any plug connectors which may be arranged on the existing plastic shutter 2 for test and maintenance purposes can be used without any restrictions once the front panels 5 have been pivoted out—not shown. In particular, in this case, there is no need to provide the plug connectors individually with individual shielding and protection elements, which is complex, since, when the front panels 5 are in the pivoted-in state, they offer sufficient shielding against electromagnetic radiated emissions and against external radiation, as well as protection against accidental contact, dirt, etc. The configuration of the shielding apparatus according to the invention must in this case be matched to the height of the projecting elements.

The invention is not restricted to the explained exemplary embodiment. For example, the front panels 5 may be connected to the board 1 of the module BG1, BG2 by arranging the pivoting arrangement directly on the panel.

The mounting panel 3 and the front panel 5 may be composed of any desired electrically conductive material or of any other desired material with an electrically conductive coating or electrically conductive core which provides the desired shielding effect.

If the front panels 5 are conductively connected in some other way and an adequate shielding effect is achieved despite the small gaps that exist between the front panels 5, there is no need to use contact springs 4 to make contact between shielding apparatuses of adjacent modules BG1, BG2. The electrically conductive connection is provided, for example, by the front panels 5 being conductively connected to the ground contact via the attachment means 7 and via the boards of the modules, or by the front panels 5 being conductively connected to one another via the further contact springs and the shelf or frame.

If desired, front panels 5 of any shape may be used instead of approximately rectangular front panels 5, and these are then preferably designed such that they interlock in order to provide a surface that is as closed as possible in the situation in which the front panels of all the modules BG1, BG2 in a shelf or frame T are pivoted in or closed.

In order that control elements, display elements and connecting elements which are integrated in the existing plastic shutters can still be used, appropriate openings may be provided in the front panels 5 of the shielding apparatuses, provided that these openings ensure compliance with the limit values for interference emissions.

In order to achieve two preferred positions (completely pivoted in and completely pivoted out) for the front panels 5, locking or clamping apparatuses whose technology is well known—but which are not shown—may be used in conjunction with the present invention. This may be accomplished, for example, in the same way apparatuses for locking the completely pivoted-in front panels 5 and apparatuses for pivoting out the front panels 5 when locked in the pivoted-in state—not shown.

Instead of separate locking or clamping apparatuses, the spring effect of the contact springs 4 may be used to hold the front panel 5 of the shielding apparatus in the completely pivoted-in state. To do this, it may be necessary to provide a depression, or a bead, in or on the mounting panel 3, into which the contact springs 4 latch, and which defines the preferred position for the pivoted-in front panel 5.

Provided that the overall shielding effect of the front panels 5 and of the contact with the shielding apparatus, according to the invention, formed from the contact springs 4, the further contact springs, the contact surfaces of the mounting panel 3 and the contact surfaces of the shelf, or frame, T is adequate, there is advantageously no need for a door for the shelf, or frame, T, since the front of the shelf, or frame, T, which is formed by all the front panels 5, provides the shielding function of the door of the shelf or frame—see FIG. 4.

Although the invention has been described with reference to shelves or frames, arranged in racks, for communications systems, the invention may also be used in other electrical or information-technology systems. The modules may also be arranged in apparatuses other than in shelves or frames, for example in portable or stationary data appliances which can be expanded in a modular manner, for example portable or stationary computers—not shown.

What is claimed is:

1. A shielding apparatus for an electrical module that provides a shielding effect, comprising:
an approximately rectangular metallic front panel which is arranged on the electrical module; and
a pivoting device that allows the approximately rectangular metallic front panel to be positioned to a pivot-in state such that the approximately rectangular metallic front panel achieves the shielding effect in the pivot-in state.

2. The shielding apparatus as claimed in claim 1, wherein the approximately rectangular metallic front panels of adjacent electrical modules are designed to be approximately interlocking.

3. The shielding apparatus as claimed in claim 2, wherein the approximately rectangular metallic front panel is pivotally coupled to a board of the electrical module by a mounting panel on which the pivoting device is formed.

4. The shielding apparatus as claimed in claim 3, wherein the shielding apparatus is designed such that it can be retrofitted, by providing attachment means for attachment of the mounting panel that are arranged and formed such that existing attachment means of the board of the electrical module are used.

5. The shielding apparatus as claimed in claim 4, wherein the approximately rectangular metallic front panel in the pivoted-in state approximately covers a plastic shutter on the electrical module.

6. The shielding apparatus as claimed in claim 5, wherein the approximately rectangular metallic front panel has openings for control elements, display elements and connecting elements which are integrated in the plastic shutter of the electrical module.

7. The shielding apparatus as claimed in claim 6, wherein the approximately rectangular metallic front panel has contact springs for producing an electrical connection for the shielding apparatus of an adjacent electrical module.

8. The shielding apparatus as claimed in claim 6, wherein the approximately rectangular metallic front panel has contact springs for producing an electrical connection for a shielding surface of an adjacent electrical module.

9. The shielding apparatus as claimed in claim 6, wherein the approximately rectangular metallic front panel has contact springs for producing an electrical connection for a shielding surface of a module shelf or a module frame.

10. The shielding apparatus as claimed in claim 7, wherein the contact springs are arranged on an edge of the approximately rectangular metallic front panel opposite the pivoting device.

11. The shielding apparatus as claimed in claim 8, wherein the contact springs are arranged on an edge of the approximately rectangular metallic front panel opposite the pivoting device.

12. The shielding apparatus as claimed in claim 9, wherein the contact springs are arranged on an edge of the approximately rectangular metallic front panel opposite the pivoting device.

13. The shielding apparatus as claimed in claim 6, wherein the pivoting device is formed by at least one of the following group consisting of a hinge, a strip and an elastic band.

14. The shielding apparatus as claimed in claim 13, wherein the attachment means for attachment of the mounting plate to the board of the module are formed by one of the following group consisting of a drilling with a riveted joint, a screwed joint, clamping attachment means or adhesives, and a combination of said attachment means.

15. The shielding apparatus as claimed in claim 1, wherein the approximately rectangular metallic front panel has contact springs for producing an electrical connection for the shielding apparatus of an adjacent electrical module.

16. The shielding apparatus as claimed in claim 1, wherein the approximately rectangular metallic front panel has contact springs for producing an electrical connection for a shielding surface of a module shelf or a module frame.

17. The shielding apparatus as claimed in claim 15, wherein the contact springs are arranged on an edge of the approximately rectangular metallic front panel opposite the pivoting device.

18. The shielding apparatus as claimed in claim 16, wherein the contact springs are arranged on an edge of the approximately rectangular metallic front panel opposite the pivoting device.

19. The shielding apparatus as claimed in claim 1, wherein the pivoting device is formed by at least one of the following group consisting of a hinge, a strip and an elastic band.
